(19) United States
(12) Patent Application Publication
(10) Pub. No.: US 2011/0242782 A1
(43) Pub. Date: Oct. 6, 2011

(54) SUBSTRATE FOR AN ELECTRICAL DEVICE

(76) Inventor: CHUNG-CHENG WANG, Taichung (TW)

(21) Appl. No.: 13/079,844

(22) Filed: Apr. 5, 2011

(30) Foreign Application Priority Data
Apr. 6, 2010 (TW) 99110495

(51) Int. Cl. H05K 7/02; H05K 1/02; H05K 1/11

(52) U.S. Cl. 361/783; 174/250; 174/262

(57) ABSTRACT

Substrate for electrical devices is disclosed. An embodiment for the substrate comprised of an insulator and a conductive element(s), wherein the conductive element embedded in the insulator, said conductive element also enables to be comprised of an upper portion(s) and a lower portion(s) which are unitary and stack; wherein the surfaces of said conductive element contacted with said insulator enables to be increased, then said conductive layer can be held by said insulator more securely, in this manner, it enables to be prevented said conductive element from peeling off said insulator, and then the reliability of said substrate in accordance with the present invention enables to be enhanced; meanwhile, said substrate can further include a chip which is embedded therein, in order that said substrate being capable of affording a thinner electrical device thickness and enhanced reliability.

### BACKGROUND OF THE INVENTION

1. Field of the Invention

This present invention is related to a substrate for electrical device, and more particularly to a substrate which is enhancing the reliability of electrical device and downsizing an electrical device.

2. Description of the Related Art

Nowadays, both the science and the technology are developing rapidly, and electrical devices are designed for thinner, lighter, smaller, wider application, lower cost, and better quality, wherein the better quality of electrical device includes higher reliability, in order to achieve above objects, manufacturers keep on developing it.

FIG. 16 shows a conventional electrical device 1A comprising a substrate 5, a chip 20, a plurality of conductive wires 60 and an encapsulant 10; said substrate 5 including an insulator 40, two conductive traces 7 and a via 7K; said insulator 40 having a side edge 44, a first surface 41 and a corresponding second surface 42; each conductive trace 7 having a side edge 7C, a first upper surface 7A and a corresponding first lower surface 7B, said conductive traces 7 situated on the surfaces of said insulator 40 (i.e. the first lower surface 7B of a conductive trace 7 is situated on the first surface 41, and the first lower surface 7B of the other conductive trace 7 is situated on the second surface 42) respectively; said via 7K encapsulated by said insulator 40 is electrically connected the conductive trace 7 situated on the first surface 41 of insulator 40 to the conductive trace 7 situated on the second surface 42 of insulator 40, wherein said via 7K is formed by a plurality of processes (such as drilling, electrical plating and/or filling etc.), as this result, the cost for manufacturing said substrate 5 becomes higher; said chip 20 having a side edge 24, a first surface 21, a corresponding second surface 22 and a plurality of bond pads 23 which are disposed on the first surface 21 of chip 20 for external connection, said second surface 22 of chip 20 being mounted on said first surface 41 of insulator 40; a conductive wire 60, wherein one end of said conductive wire 60 electrically connected said bond pad 23 of chip 20 and the other end of said electrical wire 60 electrically connected to the electrical trace 7 on the first surface 41 of insulator 40, in this manner, said chip 20 enables to electrically connected to the substrate 5 through said electrical wire 60; said encapsulant 10 which is situated on said first surface 41 of said insulator 40 seals said substrate 5, said chip 20, and said electrical wire 60;

According to the conventional electrical device 1A shown in FIG. 16, due to the chip 20, conductive traces 7 and said encapsulant 10 are all coupled with the insulator 40 of substrate 5, then the thickness “Ta” of said electrical device 1A is the sum of the thickness T5 of substrate 5, the thickness T20 of chip 20 and the thickness T10 of encapsulant 10, wherein the thickness T5 of substrate 5 consists of both the thickness T40 of insulator 40 and the thickness T7 of conductive traces 7; Consequently, it causes the thickness “Ta” of electrical device 1A to become thicker and larger; As it has been mentioned above that the electrical devices are designed for thinner, lighter, smaller, wider application, lower cost, and better quality, wherein For satisfying the results mentioned above, Usually, one of effective methods for achieving above objects is decrease both the thickness T7 of conductive trace 7 and the thickness T20 of chip 20, Nevertheless, it is necessary to purchase extra facilities to achieve above objects, then it causes the cost higher, Moreover, both the thickness T7 of conductive trace 7 and the thickness T20 of chip 20 can not be “zero” (that is to say both the thickness T7 of conductive trace 7 and the thickness T20 of chip 20 shown in FIG. 16 are always existing, meanwhile, in case that both the thickness T7 of conductive trace 7 and the thickness T20 of chip 20 become “zero”, then it means both the conductive trace 7 and the chip 20 are omitted); Accordingly, due to both the thickness T7 of conductive trace 7 and the thickness T20 of chip 20 always exist, it is difficult to reduce the thickness “Ta” of electrical device 1A effectively, as this result, the applications for said substrate 5 and said electrical device 1A are restricted.

### SUMMARY OF THE INVENTION

It is therefore an object of the invention to solve the mentioned-above problems, in accordance with the invention, the substrate includes an insulator and a plurality of conductive elements, wherein the conductive elements are embedded in the insulator, and a portion of conductive element exposed to the insulator for external connection, wherein By means of the conductive elements being embedded in the insulator, in this manner, the thickness of said substrate can be thinner, it is good for the electronic industries, furthermore, the surfaces of said conductive elements contacted with said insulator enables to be increased, then said conductive elements can be held by said insulator more securely, then, it enables to be prevented said conductive elements from peeling off said insulator, and then the reliability of said substrate in accordance with the present invention enables to be enhanced; and wherein said conductive element also enables to be comprised of an upper portion(s) and a lower portion(s) which are stack and unitary, due to the upper portion(s) and a lower portion(s) mentioned-above, Not only is omitted the via in the insulator of substrate but said conductive element enables to be held by the insulator more securely, as this result, Both the cost for manufacturing said substrate in accordance with the present invention enables to be saved and the reliability of said substrate in accordance with the present invention enables to be enhanced; meanwhile, said substrate can further include a chip which is embedded in the insulator too, in order that said substrate in accordance with the invention is capable of affording a thinner thickness and an enhanced reliability for electrical device;

The aforementioned and further objects of the present invention will be more adequately appeared from the detailed description, accompanying drawings and appended claims as follow.

### BRIEF DESCRIPTION OF THE DRAWINGS

FIG. 1A shows a top view of substrate in accordance with the present invention.

FIG. 1B shows a cross-sectional view of substrate in accordance with the present invention taken along the “CL” line in FIG. 1A.

FIG. 1C shows a cross-sectional view of substrate in accordance with the present invention taken along the “CL” line in FIG. 1A.

FIG. 1D shows a cross-sectional view of substrate in accordance with the present invention taken along the “CL” line in FIG. 1A.

FIG. 2A shows a top view of substrate in accordance with the present invention.

FIG. 2B shows a cross-sectional view of substrate in accordance with the present invention taken along the “CL” line in FIG. 2A.

FIGS. 3-5 are cross-sectional views of substrate in accordance with the present invention.

FIG. 6 shows a cross-sectional view of substrate in accordance with the present invention, wherein first conductive layers involved therein.

FIG. 7 shows a cross-sectional view of substrate in accordance with the present invention, wherein first conductive layers and second conductive layers involved therein.

FIG. 8 shows a cross-sectional view of substrate in accordance with the present invention, wherein a third insulator involved therein.

FIG. 9 shows a cross-sectional view of substrate in accordance with the present invention, wherein a third insulator, a second conductive element, and a protective layer involved therein.

FIG. 10 shows a cross-sectional view of substrate in accordance with the present invention, wherein a plurality of third insulators involved therein.

FIGS. 11-12 are cross-sectional views of substrate in accordance with the present invention, wherein a chip involved therein.

FIGS. 13-14 are cross-sectional views of substrate in accordance with the present invention, wherein a chip associated with a conductive mean involved therein.

FIGS. 15 is a cross-sectional view showing an embodiments of electrical device, wherein the substrate according to the present invention is involved therein.

FIG. 16 shows a cross-sectional view of electrical device according to a prior art.

### DETAILED DESCRIPTION OF PREFERRED EMBODIMENTS

Embodiments of the present invention will be explained with reference to the drawings as follow.

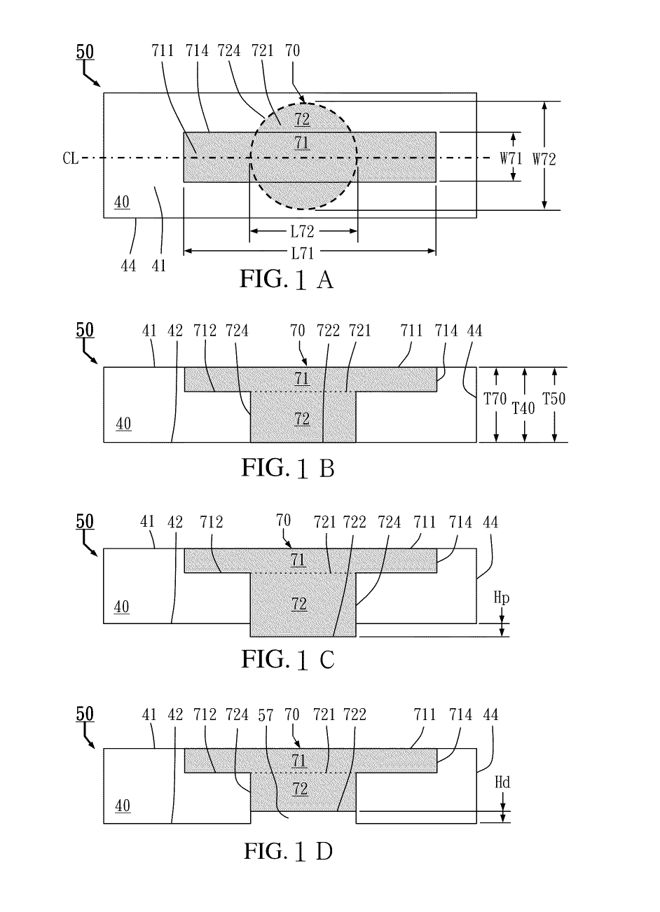

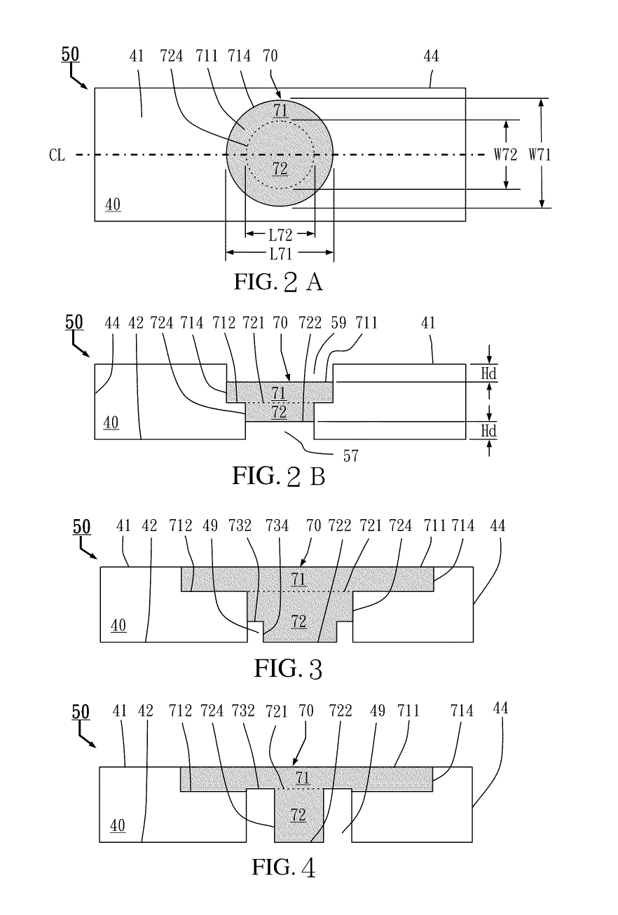

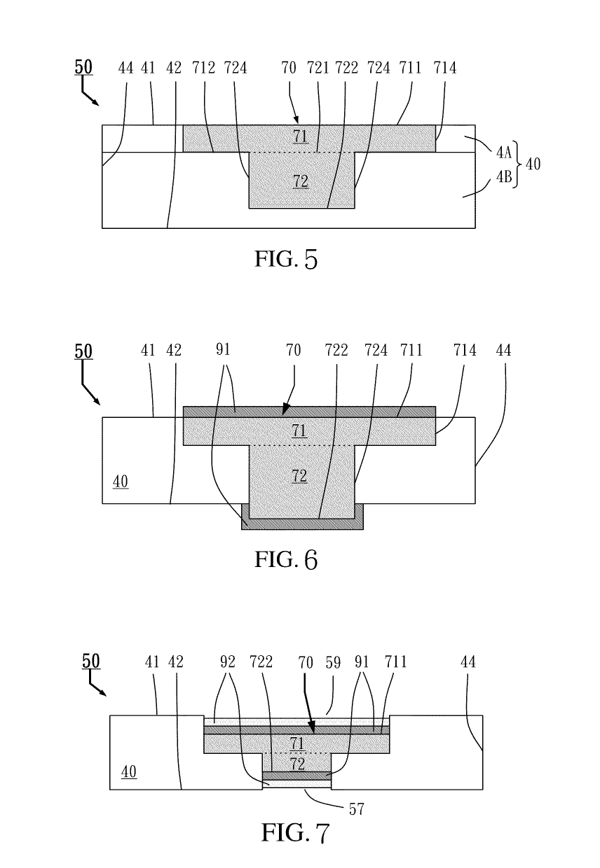

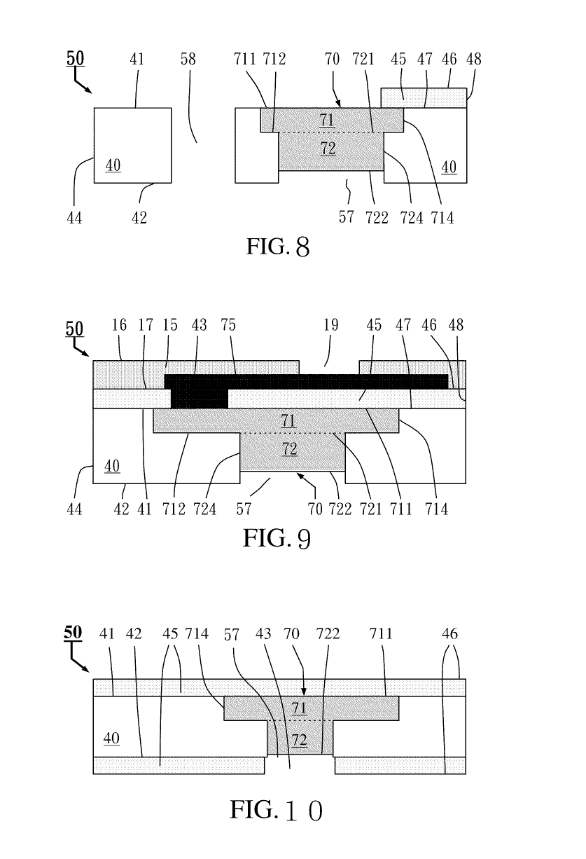

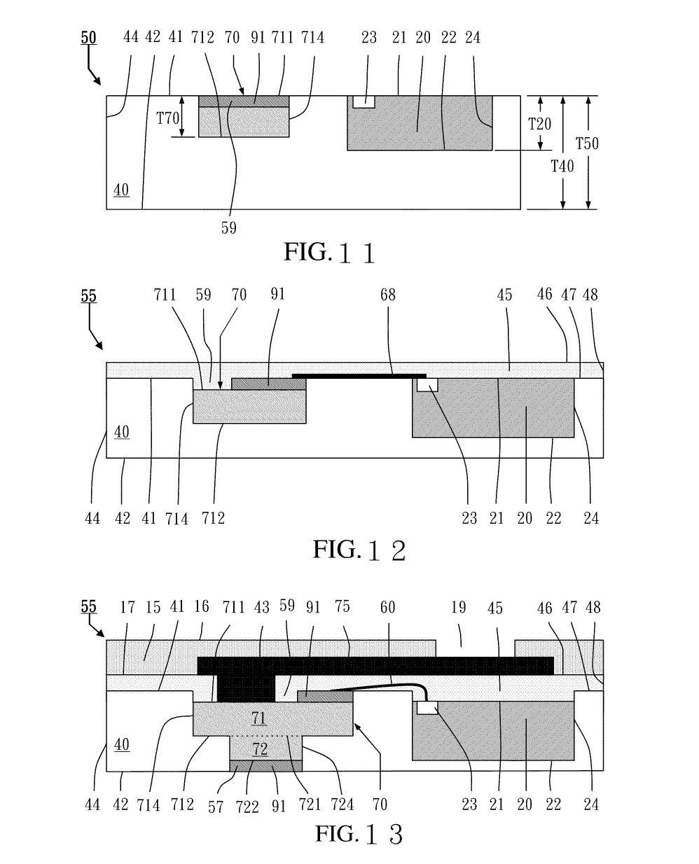

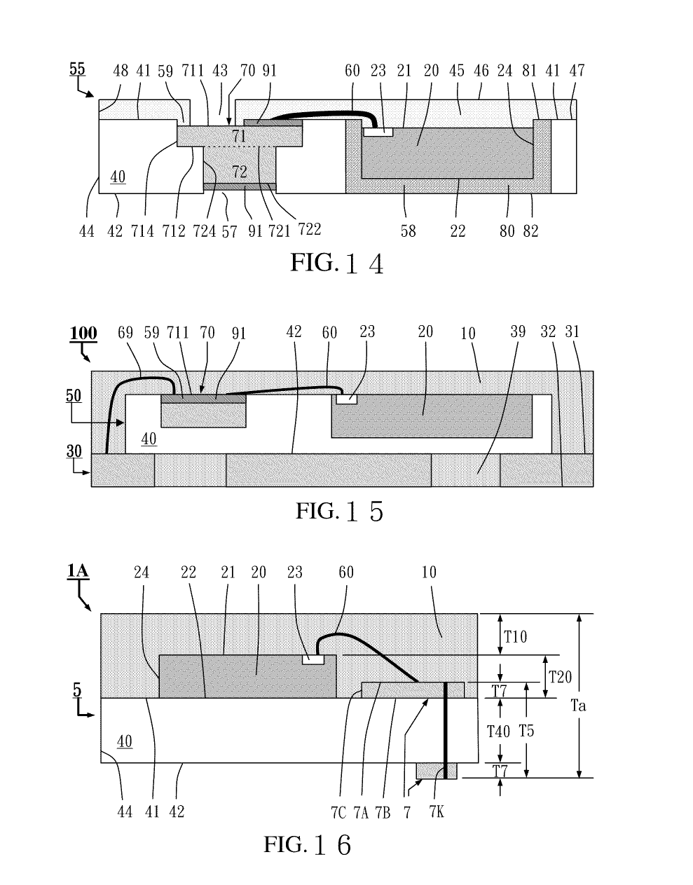

Embodiments shown in FIGS. 1A˜1D are the basic structures of the substrate 50 in accordance with the present invention, wherein FIG. 1A is the top view of substrate 50, FIGS. 1B˜1D are the cross-sectional views of substrate 50 taken along the “CL” line in FIG. 1A, detailed descriptions are following:

As shown in FIG. 1A and FIG. 1B, the substrate 50 comprising: an insulator 40 which is made of insulative material such as epoxy, ceramic, resin, solder mask, polyimide or the like, said insulator 40 having a side edge 44, a first surface 41, and a corresponding second surface 42, wherein said insulator 40 is unitary, then, the reliability of said insulator 40 can be enhanced (due to said insulator 40 can avoid peeling-off problems caused by said interface); a conductive element 70 which is predetermined shape is made of conductive material such as copper, copper alloy, nickel, aluminum, titanium, metallic alloy or the like, said conductive element 70 is comprised of an upper portion 71 and a lower portion 72, said upper portion 71 of conductive element 70 having a first side edge 714, a first width “W71”, a first length “L71”, a first upper surface 711, and a corresponding first lower surface 712, wherein the first upper surface 711 of said upper portion 71 is also employed as the first upper surface of said conductive element 70, said lower portion 72 having a second side edge 724, a second width “W72”, a second length “L72”, a second upper surface 721, and a corresponding second lower surface 722, wherein the second lower surface 722 of said lower portion 72 is also employed as the second lower surface of said conductive element 70, wherein both the upper portion 71 and the lower portion 72 are stack and enable to be electrically connected each other, meanwhile, said upper portion 71 is common unitary with said lower portion 72 of conductive element 70, wherein a portion of said first lower surface 712 of said upper portion 71 is coupled with said second upper surface 721 of said lower portion 72, in this manner, both said upper portion 71 and said lower portion 72 are stack; said conductive element 70 (i.e. both said upper portion 71 and said lower portion 72) is encapsulated by said insulator 40 and embedded therein, wherein said first lower surface 712 and said first side edge 714 of said upper portion 71 are encapsulated by said insulator 40, however, the first upper surface 711 of upper portion 71 in not encapsulated but exposed to said first surface 41 of insulator 40; said second upper surface 721 and said second side edge 724 of said lower portion 72 are encapsulated by said insulator 40 too, Nevertheless, It is optional that said lower portion 72 being encapsulated by said insulator 40 (refer to the detailed descriptions in FIG. 4), the second lower surface 722 of lower portion 72 is not encapsulated but exposed to said second surface 42 of insulator 40, and wherein both the first upper surface 711 of upper portion 71 and the first surface 41 of insulator 40 are co-planar, both the second lower surface 722 of lower portion 72 and the second surface 42 of insulator 40 are co-planar too, accordingly, the thickness T70 of said conductive element 70 is the same as the thickness T40 of said insulator 40; the length of said first length “L71” of upper portion 71 is longer than the length of said second length “L72” of lower portion 72, in this manner, said first lower surface 712 of upper portion 71 is not coupled with said second upper surface 721 of lower portion 72 entirely, and therefore said upper portion 71 is capable of extending on said first surface 41 of insulator 40, as this result, it is convenient for said substrate 50 to be used in the electronic industries; In addition, A portion of said first side edge 714 of upper portion 71 (refer to FIG. 1B) enables to be exposed to said side edge 44 of insulator 40 as required, Moreover, due to both the second upper surface 721 and the second side edge 724 of said lower portion 72 are encapsulated by said insulator 40, then the surfaces of said conductive element 70 encapsulated by said insulator 40 are increased, and then said conductive element 70 can be held by said insulator 40 more securely, in this manner, It can prevent said conductive element 70 from peeling off said insulator 40, therefore, the reliability of said substrate 50 is enhanced; furthermore, the width of said second width “W72” of lower portion 72 is wider than the width of said first width“W71” of upper portion 71, in this manner, said second upper surface 721 of lower portion 72 is not coupled with said first lower surface 712 of upper portion 71 entirely, and therefore, said lower portion 72 is capable of extending on said second surface 42 of insulator 40; then it is also convenient for said substrate 50 to be used in the electronic industries, In addition, due to said conductive element 70 encapsulated by said insulator 40, then both the thickness T70 of said conductive element 70 and the thickness T40 of said insulator 40 are the same as said thickness T50 of substrate 50, wherein, although the thickness T50 of substrate 50 includes both the thickness T70 of conductive element 70 and the thickness T40 of insulator 40, however, due to said conductive element 70 is encapsulated by said insulator 40, and the thickness T70 of conductive element 70 is equal to the thickness T40 of insulator 40, in this manner, the thickness T70 of said conductive element 70 can be omitted, then the thickness T50 of said substrate 50 includes the thickness T40 of insulator 40 exclusively, as this result, the thickness T50 of said substrate 50 enables to be decreased effectively, and then said substrate 50 can actually become smaller, lighter, and shorter, It is good for the electronic industries; In addition, due to said upper portion 71 and said lower portion 72 are unitary, then (i). it allows that said upper portion 71 electrically connected to said lower portion 72, in this manner, the via (shown in FIG. 16, “7K”) is omitted; and (ii). there is not any interface between said upper portion 71 and said lower portion 72, accordingly, the reliability of said conductive element 70 is enhanced (because, for example: in case of two conductive materials such as an upper portion and a lower portion which are conjugated by a build-up process while manufacturing a conductive element, there is an interface occurred, said interface is formed by the conjugation surfaces of said two conductive materials, once there is an interface mentioned-above between said two conductive materials, it is risky for the conjugation surface of said two conductive materials to be contaminated by either chemical articles (such as solvent etc.) or oxidation, then it is easy for said two conductive materials to cause crack problem(s) and/or impedance problem(s), as this result, the reliability of substrate becomes poor.).

As shown in FIG. 1A and FIG. 1C, said FIG. 1A is the top view of substrate 50, said FIG. 1C is the cross-sectional views of substrate 50 taken along the “CL” line in FIG. 1A; the structure of substrate 50 (shown in FIG. 1A and FIG. 1C) is similar to the structure of substrate 50 (shown in FIG. 1A and FIG. 1B), wherein the difference between the substrate 50 shown in FIG. 1C and the substrate 50 shown in FIG. 1B is the second lower surface 722 of conductive element 70 shown in FIG. 1C is protruding the second surface 42 of insulator 40 as required, therefore, there is a height “Hp” between said second lower surface 722 of conductive element 70 and said second surface 42 of insulator 40, then a portion of the second side edge 724 is exposed to the second surface 42 of insulator 40, in this manner, the surfaces of said conductive element 70 contacted with the external connection (such as solder ball (not shown), solder paste (not shown), or the like) is increased (due to Not only the second lower surface 722 of conductive element 70 enables to be connected to said external connection but the portion of the second side edge 724 exposed to the second surface 42 of insulator 40 also enables to be connected to said external connection), in this manner, said conductive element 70 enables to be connected to said external connection more securely, and then the reliability of said substrate 50 can be enhanced; Meanwhile, the first upper surface 711 of conductive element 70 shown in FIG. 1C can also be protruding the first surface 41 of insulator 40 as required, then a portion of the first side edge 714 enable to be exposed to the first surface 41 of insulator 40, and then the reliability of said substrate 50 can be enhanced too.

As shown in FIG. 1A and FIG. 1D, said FIG. 1A is the top view of substrate 50, said FIG. 1D is the cross-sectional views of substrate 50 taken along the “CL” line in FIG. 1A, the structure of substrate 50 (shown in FIG. 1A and FIG. 1D) is similar to the structure of substrate 50 (shown in FIG. 1A and FIG. 1B), wherein the difference between the substrate 50 shown in FIG. 1D and the substrate 50 shown in FIG. 1B is the second lower surface 722 of conductive element 70 shown in FIG. 1D is below and exposed to the second surface 42 of insulator 40 as required, therefore, there is a depth “Hd” between said second lower surface 722 of conductive element 70 and said second surface 42 of insulator 40, and then a recess 57 is formed by said second lower surface 722 of conductive element 70 and said insulator 40, in this manner, a conductive layer (refer to FIG. 7, “91” and/or “92”) enables to be placed in said recess 57 without increasing the thickness of said substrate 50 (the advantages of said conductive layer, please refer to the detailed description in FIG. 7), It is good for the electronic industries;

As shown in FIG. 2A and FIG. 2B, said FIG. 2A is the top view of substrate 50, said FIG. 2B is the cross-sectional views of substrate 50 taken along the “CL” line in FIG. 2A; FIG. 2A and FIG. 2B showing the substrate 50 comprising: an insulator 40 having a side edge 44, a first surface 41, and a corresponding second surface 42, and said insulator 40 is unitary; a conductive element 70 having an upper portion 71 and a lower portion 72, said upper portion 71 of conductive element 70 having a first side edge 714, a first width “W71”, a first length “L71”, a first upper surface 711, and a corresponding first lower surface 712, wherein the first upper surface 711 of said upper portion 71 is also employed as the first upper surface of said conductive element 70; said lower portion 72 having a second side edge 724, a second width “W72”, a second length “L72”, a second upper surface 721, and a second lower surface 722, wherein the second lower surface 722 of said lower portion 72 is also employed as the second lower surface of said conductive element 70, meanwhile, both the upper portion 71 and the lower portion 72 are unitary, wherein a portion of said first lower surface 712 of said upper portion 71 is coupled with said second upper surface 721 of said lower portion 72, in this manner, both said upper portion 71 and said lower portion 72 are stack and enable to be electrically connected each other; said conductive element 70 (i.e. both said upper portion 71 and said lower portion 72) is encapsulated by said insulator 40 and embedded therein, wherein said first lower surface 712 and said first side edge 714 of said upper portion 71 are encapsulated by said insulator 40, and the first upper surface 711 of upper portion 71 exposed to said first surface 41 of insulator 40, and wherein said second upper surface 721 and said second side edge 724 of said lower portion 72 are encapsulated by said insulator 40 too, However, said second side edge 724 of said lower portion 72 being encapsulated by said insulator 40 is optional (refer to the detailed descriptions in FIG. 4); wherein the first upper surface 711 of conductive element 70 shown in FIG. 2B is below and exposed to the first surface 41 of insulator 40, therefore, there is a depth “Hd” between said first upper surface 711 of conductive element 70 and said first surface 41 of insulator 40, then a recess 59 is formed by said first upper surface 711 of conductive element 70 and said insulator 40; meanwhile, the second lower surface 722 of conductive element 70 is below and exposed to the second surface 42 of insulator 40 too, therefore there is a depth “Hd” between said second lower surface 722 of conductive element 70 and said second surface 42 of insulator 40 too, then a recess 57 is formed by said second lower surface 722 of conductive element 70 and said insulator 40, in this manner, conductive layers (refer to FIG. 7, “91” and/or “92”) enable to be placed in both said recess 57 and said recess 59 without increasing the thickness of said substrate 50 (the advantages of said conductive layers, please refer to the detailed description in FIG. 7), It is good for the electronic industries;

As shown in FIG. 3, the substrate 50 in FIG. 3 is an alternative of the substrate 50 shown in FIG. 1B; the structure of substrate 50 (shown in FIG. 3) is similar to the structure of substrate 50 (shown in FIG. 1B), wherein the difference between the substrate 50 shown in FIG. 3 and the substrate 50 shown in FIG. 1B is the lower portion 72 of conductive element 70 (shown in FIG. 3) further includes a third lower surface 732 and a third side edge 734 which are between the second lower surface 722 of conductive element 70 and the insulator 40 as required, therefore, there is a slot 49 formed by said third side edge 734, said third lower surface 732 and said insulator 40; wherein both said third side edge 734 and said third lower surface 732 are not encapsulated by said insulator 40 but exposed to said insulator 40, accordingly, the surfaces of said lower portion 72 contacted with the external connection (such as solder ball (not shown), solder paste (not shown) or the like) enables to be increased, in this manner, said conductive element 70 enables to be connected to said external connection more securely, and then the reliability of said substrate 50 can be enhanced; Moreover, said slot 49 of substrate 50 can also be accommodating for conductive materials such as solder ball, solder paste, conductive layer or the like.

As shown in FIG. 4, the substrate 50 in FIG. 4 is an alternative of the substrate 50 shown in FIG. 1B; the structure of substrate 50 (shown in FIG. 4) is similar to the structure of substrate 50 (shown in FIG. 1B), wherein the difference between the substrate 50 shown in FIG. 4 and the substrate 50 shown in FIG. 1B is: the upper portion 71 of conductive element 70 (shown in FIG. 4) further includes a third lower surface 732 which is between the first lower surface 712 of said upper portion 71 and the second side edge 724 of said lower portion 72 as required, therefore, there is a slot 49 formed by said second side edge 724, said third lower surface 732 and said insulator 40; wherein both said second side edge 724 and said third lower surface 732 are not encapsulated by said insulator 40 but exposed to said insulator 40, accordingly, the surfaces of said lower portion 72 contacted with the external connection (such as solder ball (not shown), solder paste (not shown) or the like) enables to be increased, in this manner, said conductive element 70 enables to be connected to said external connection more securely, and then the reliability of said substrate 50 can be enhanced; Moreover, said slot 49 of substrate 50 can also be accommodating for conductive materials such as solder ball, solder paste, conductive layers or the like.

As shown in FIG. 5, the substrate 50 in FIG. 5 is an alternative of the substrate 50 shown in FIG. 1D; the structure of substrate 50 (shown in FIG. 5) is similar to the structure of substrate 50 (shown in FIG. 1D), wherein the differences between the substrate 50 shown in FIG. 5 and the substrate 50 shown in FIG. 1D are (i). the second lower surface 722 of conductive element 70 (shown in FIG. 5) is encapsulated by said insulator 40 too, in this manner, said second lower surface 722 of conductive element 70 is not exposed to said insulator 40; and (ii). (still in FIG. 5), said insulator 40 is comprised of a first insulator 4A and a second insulator 4B which are stack, and said insulator 40 having a first surface 41, a corresponding second surface 42, and a side edge 44, wherein the first side edge 714 of upper portion 71 of conductive element 70 is encapsulated by said first insulator 4A; said first lower surface 712, said second side edge 724 of lower portion 72 and said second lower surface 722 of lower portion 72 are encapsulated by said second insulator 4B, wherein both said first insulator material 4A and said second insulator 4B can be made of either the same material which is the same coefficient of thermal expansion or different materials which are different coefficient of thermal expansion in order to avoid warpage problems, then the reliability of substrate 50 can be enhanced; In addition, the first upper surface 711 of conductive element 70 can also be encapsulated by said insulator 40 as required too.

The substrate 50 (shown in FIGS. 1A˜5,) in accordance with the present invention, wherein the first upper surface 711 or the second lower surface 722 of conductive element 70 can be exposed or not exposed to the first surface 41 or the second surface 42 of insulator 40 as required, Moreover, the first upper surface 711 or the second lower surface 722 of conductive element 70 can be protruding or not protruding the first surface 41 or the second surface 42 of insulator 40 as required too; In addition, the substrate 50 can further include a solder mask, a conductive layer, and/or a chip etc., so that it is more convenient for said substrate 50 to be used in the electronic industries (refer to FIG. 6˜15 which are cross-sectional views of embodiments in accordance with the present invention), detailed descriptions as following:

As shown in FIG. 6, the substrate 50 in FIG. 6 is an alternative of the substrate 50 shown in FIG. 1C; the structure of substrate 50 (shown in FIG. 6) is similar to the structure of substrate 50 (shown in FIG. 1C), wherein the difference between the substrate 50 shown in FIG. 6 and the substrate 50 shown in FIG. 1C is the substrate 50 (shown in FIG. 6) further includes a plurality of conductive layers which are employed as first conductive layers 91, said first conductive layers 91 are made of nickel, palladium, silver, copper or the like for enhancing the electrical connection quality with external connection(such as gold, tin, nickel, palladium, silver, copper etc.), said first conductive layers 91 are situated on the portions of conductive element 70 which are exposed to the insulator 40 (i.e. the first upper surface 711, the second lower surface 722, and the portion of said second side edge 724 which is exposed to the insulator 40) respectively; Consequently, the portion(s) of said conductive element 70 exposed to said insulator 40 enable to be situated at least a conductive layer thereon for enhancing the quality of electrical connection; moreover, due to a conductive layer(s) being situated on said conductive element 70, then said conductive layer(s) become(s) a part(s) of said conductive element 70, and then the surface(s) of conductive element 70 exposed to the insulator 40 being formed by said conductive layer(s) as required.

As shown in FIG. 7, the substrate 50 in FIG. 7 is an alternative of the substrate 50 shown in FIG. 2B; the structure of substrate 50 (shown in FIG. 7) is similar to the structure of substrate 50 (shown in FIG. 2B), wherein the difference between the substrate 50 shown in FIG. 7 and the substrate 50 shown in FIG. 2B is the substrate 50 (shown in FIG. 7) further includes a plurality of first conductive layers 91 and second conductive layers 92, wherein each first conductive layer 91 is situated on the first upper surface 711 and the second lower surface 722 of conductive element 70 respectively, and each second conductive layer 92 is situated on each first conductive layer 91 respectively too, in this manner, the second conductive layer 92 and the first conductive layer 91 on the first upper surface 711 are placed within the recess 59 formed by said first upper surface 711 and said insulator 40, meanwhile, the other second conductive layer 92 and the other first conductive layer 91 on the second lower surface 722 are placed within the recess 57 formed by said second lower surface 722 and said insulator 40; For better understanding, at first, refer to both the first conductive layers 91 and the second conductive layer 92 on the first upper surface 711 which are placed within the recess 59, wherein, the first conductive layer 91 is between the first upper surface 711 and the second conductive layer 92, and wherein the side edge (numeral not shown in FIG. 7) of said first conductive layer 91 and the side edge (numeral not shown in FIG. 7) of said second conductive layer 92 are all encapsulated by said insulator 40, in this manner, due to both the first conductive layer 91 and the second conductive layer 92 on the first upper surface 711 are placed within the recess 59, and the side edge of first conductive layer 91 and the side edge of second conductive layer 92 are encapsulated by said insulator 40, then (i). the surfaces of said conductive layers (i.e. said first conductive layer 91 and said second conductive layer 92) contacted with said insulator 40 enable to be increased, therefore, said conductive layers can be held by said insulator 40 more securely, and then it can prevent said conductive layers from peeling off said insulator 40, as this result, the reliability of said substrate 50 is enhanced; (ii). Due to said conductive layers are placed in said recess 59 without increasing the thickness of said substrate 50, then the thickness of said substrate 50 is still thinner, it is good for the electronic industry; and (iii). the reliability of electrical connection for said substrate 50 can be enhanced; And now turning back to the other first conductive layer 91 and the other second conductive layer 92 on the second lower surface 722 which are placed within the recess 57 formed by said second lower surface 722 and said insulator 40, wherein due to both the first conductive layer 91 and the second conductive layer 92 on the second lower surface 722 are placed within the recess 57, and the side edge of first conductive layers 91 and the side edge of second conductive layer 92 are encapsulated by said insulator 40, then It also allows (i). the reliability of said substrate 50 is enhanced; (ii). the thickness of said substrate 50 is still thinner; and (iii). the reliability of electrical connection for said substrate 50 can be enhanced too.

As shown in FIG. 8, the substrate 50 in FIG. 8 is an alternative of the substrate 50 shown in FIG. 1D; the structure of substrate 50 (shown in FIG. 8) is similar to the structure of substrate 50 (shown in FIG. 1D), wherein the differences between the substrate 50 shown in FIG. 8 and the substrate 50 shown in FIG. 1D are (i). the substrate 50 (shown in FIG. 8) further includes a third insulator 45, said third insulator 45 having a side edge 48, a first surface 46 and a corresponding second surface 47; said second surface 47 of third insulator 45 situated on said first surface 41 of insulator 40, wherein, a portion of the first upper surface 711 of conductive element 70 is not encapsulated by said third insulator 45 but exposed to said third insulator 45 for external connection, By means of said third insulator 45, It enables to prevent said substrate 50 from short problems caused by corrosion, impact etc.; and (ii). (still in FIG. 8), said insulator 40 of said substrate 50 is comprised of a through hole 58 for accommodating a chip, an adhesive mean such as glue, or the like as required.

As shown in FIG. 9, the substrate 50 in FIG. 9 is an alternative of the substrate 50 shown in FIG. 1D; the structure of substrate 50 (shown in FIG. 9) is similar to the structure of substrate 50 (shown in FIG. 1D), wherein the differences between the substrate 50 shown in FIG. 9 and the substrate 50 shown in FIG. 1D is: the substrate 50 (shown in FIG. 9) further includes a third insulator 45, a second conductive element 75, a protective layer 15, and a third insulator 45; said third insulator 45 having a side edge 48, an opening 43, a first surface 46 and a corresponding second surface 47; said second surface 47 of third insulator 45 situated on said first surface 41 of insulator 40, wherein, a portion of the first upper surface 711 of conductive element 70 is not encapsulated by said third insulator 45 but exposed to said opening 43 of third insulator 45 for external connection; said second conductive element 75 which is for re-layout is situated on the first surface 46 of third insulator 45 and is electrically connected to said conductive element 70 through said opening 43 of third insulator 45; said protective layer 15 is made of insulative material such as epoxy, glue, resin, solder mask and/or the like, said protective layer 15 having an opening 19, a first surface 16 and a corresponding second surface 17, said second surface 17 of protective layer 15 is situated on said first surface 46 of third insulator 45, and said second conductive element 75 is encapsulated by said protective layer 15, wherein a portion of said second conductive element 75 is exposed to the opening 19 of protective layer 15 for external connection; Consequently, By means of the second conductive element 75, Not only the first upper surface 711 of conductive element 70 of said substrate 50 enables to be for external connection but the second conductive element 75 enables to be for external connection, then It allows said substrate 50 to be used more conveniently and more flexibly in the industries;

As shown in FIG. 10, the substrate 50 in FIG. 10 is an alternative of the substrate 50 shown in FIG. 1D; the structure of substrate 50 (shown in FIG. 10) is similar to the structure of substrate 50 (shown in FIG. 1D), wherein the differences between the substrate 50 shown in FIG. 10 and the substrate 50 shown in FIG. 1D is: the substrate 50 (shown in FIG. 10) further includes two third insulators 45 ,said third insulators 45 are situated on the first surface 41 and the second surface 42 of insulator 40 respectively, therefore, the first upper surface 711 of conductive element 70 enables to be encapsulated by said third insulator 45 on the first surface 41 of insulator 40 entirely, Nevertheless, the third insulator 45 on the second surface 42 of insulator 40 having an opening 43 which is corresponding to said recess 57, in this manner, a portion of the second lower surface 722 of conductive element 70 is not encapsulated by said third insulator 45 but exposed to said opening 43 third insulator 45 for external connection, Consequently, It allows said substrate 50 to be used more conveniently and more flexibly in the industries.

As shown in FIG. 11, the substrate 50 shown in FIG. 11 is compared with the substrate 5 shown in FIG. 16, wherein the thickness of insulator 40 and the thickness of chip 20 shown in FIG. 11 are the same as the thickness of insulator 40 and the thickness of chip 20 shown in FIG. 16, and the thickness of conductive element 70 shown in FIG. 11 is the same as the thickness of conductive trace 7 shown in FIG. 16; the substrate 50 shown in FIG. 11 includes an insulator 40, a conductive element 70, a first conductive layer 91, a chip 20 and a recess 59 which is formed by said first upper surface 711 of conductive element 70 and said insulator 40; said insulator 40 having a side edge 44, a first surface 41 and a corresponding second surface 42; said conductive element 70 having a first side edge 714, a first upper surface 711 and a corresponding first lower surface 712, said first side edge 714 of conductive element 70 is encapsulated by said insulator 40, in this manner, said conductive element 70 is embedded in said insulator 40, wherein said first upper surface 711 of conductive element 70 is not encapsulated by said insulator 40 but is exposed to said first surface 41 of insulator 40; said first conductive layer 91 is placed in said recess 59 of said substrate 50, and wherein said first conductive layer 91 is situated on the portion of conductive element 70 which is exposed to the insulator 40 (i.e. the first upper surface 711 of conductive element 70), wherein the side edge (numeral not shown in FIG. 11) of said first conductive layer 91 is encapsulated by said insulator 40, in this manner, said first conductive layer 91 is placed in said recess 59 without increasing the thickness of said substrate 50, Accordingly, it is good for the electronic industries; meanwhile, due to said first conductive layer 91, it is easy for said conductive element 70 to enhance the electrical connection quality with external connection (such as conductive paste (see FIG. 12, “68”), conductive wire (see FIG. 13, “60”), and/or gold, tin, nickel, palladium, silver, copper etc.); Furthermore, said side edge of first conductive layer 91 enables to be not encapsulated by said insulator 40 (refer to FIG. 6, wherein the side edge of first conductive layer 91 situated on the first upper surface 711 of conductive element 70 is not encapsulated by the insulator 40, the first upper surface 711 of conductive element 70 is co-planar to the first surface 41 of insulator 40) moreover, due to a conductive layer(s) being situated on said conductive element 70, then said conductive layer(s) become(s) a part(s) of said conductive element 70, and then the surface(s) of conductive element 70 exposed to the insulator 40 being formed by said conductive layer(s); said chip 20 having a first surface 21, a second surface 22, a bond pad(s) 23 and a side edge 24, said bond pad 23 is disposed on said first surface 21 of chip 20, wherein the side edge 24 of chip 20 is encapsulated by said insulator 40, in this manner, said chip 20 is embedded in said insulator 40, said first surface 21 of chip 20 is exposed to said first surface 41 of insulator 40, and said chip 20 is adjacent to said conductive element 70; therefore, According to said substrate 50 shown in FIG. 11, due to both conductive element 70 (associated with said first conductive layer 91) and said chip 20 are all embedded in said insulator 40, then both the thickness T20 of chip 20 and the thickness T70 of conductive element 70 can be omitted, in this manner, both the thickness T50 of substrate 50 (shown in FIG. 11) and the thickness T40 of insulator 40 are the same as each other, then, Not only it allows the conductive element 70 and the chip 20 enable to be involved in said substrate 50 without increasing the thickness T50 of said substrate 50 but it also allows the thickness T50 of substrate 50 to be thinner than the substrate 5 shown in FIG. 16; As this results, it is convenient for said substrate 50 to be used in the electronic industries; In addition, both the first lower surface 712 of conductive element 70 and the second surface 22 of chip 20 shown in FIG. 11 are encapsulated by said insulator 40 , Nevertheless, the second surface 22 of chip 20 shown in FIG. 11 enables to be not encapsulated by said insulator 40 but be exposed to the second surface 42 of said insulator 40 as required; Moreover, the first lower surface 712 of conductive element 70 shown in FIG. 11 enables to be not encapsulated by said insulator 40 but be exposed to the second surface 42 of said insulator 40 as required too.

As shown in FIG. 12, the substrate 55 in FIG. 12 is an alternative of the substrate 50 shown in FIG. 11; the structure of substrate 55 (shown in FIG. 12) is similar to the structure of substrate 50 (shown in FIG. 11), wherein the difference between said substrate 55 shown in FIG. 12 and the substrate 50 shown in FIG. 11 is said substrate 55 further includes a third insulator 45 and a conductive mean, said conductive mean is employed as a conductive paste 68 which is comprised of conductive materials such as copper, aluminum or the like, said conductive paste 68 is become solidified after operating a heating process usually, meanwhile, said conductive paste 68 can be coupled with said insulator 40, said conductive element 70, and said chip 20 etc. after operating a heating process too, wherein said bond pad 23 of chip 20 is electrically connected to said first conductive layer 91 on said conductive element 70 through the two ends of said conductive paste 68, wherein said conductive paste 68 is coupled with said chip 20, said insulator 40 and said first conductive layer 91, and wherein the path of said conductive paste 68 is: from the bond pad 23 of chip 20 alone the first surface 41 of insulator 40 to the first conductive layer 91 on conductive element 70; moreover, said conductive paste 68 can be substituted by a conductive wire (refer to FIG. 13; “60”) as required; said third insulator 45 having a side edge 48, a first surface 46 and a corresponding second surface 47, said third insulator 45 situated on the first surface 41 of insulator 40 seals said chip 20, said conductive paste 68, said first conductive layer 91, said conductive element 70 and said insulator 40; Consequently, By means of being conjoined with said conductive pastes 68, said third insulator 45 etc. it allows said substrate 55 to be used more conveniently; Furthermore, An added insulator and/or conductive elements can also be situated on the first surface 46 of said third insulator 45 or the second surface 42 of insulator 40 as required (refer to the detailed descriptions of FIG. 13).

As shown in FIG. 13, the substrate 55 in FIG. 13 is an alternative of the substrate 50 shown in FIG. 9; the structure of substrate 55 (shown in FIG. 13) is similar to the structure of substrate 50 (shown in FIG. 9), wherein the difference between said substrate 55 shown in FIG. 13 and the substrate 50 shown in FIG. 9 is said substrate 55 further includes a chip 20, two first conductive layers 91, a conductive mean which is employed as a conductive wire 60, and a recess 59 which is formed by the first upper surface 711 of conductive element 70 and said insulator 40; said chip 20 having a first surface 21, a second surface 22, a bond pad(s) 23 and a side edge 24, said bond pad 23 is disposed on said first surface 21 of chip 20, wherein the side edge 24 of chip 20 is encapsulated by said insulator 40, in this manner, said chip 20 is embedded in said insulator 40, meanwhile, said first surface 21 of chip 20 is exposed to said first surface 41 of insulator 40, and said chip 20 is adjacent to said conductive element 70; said first conductive layers 91 are situated on the first upper surface 711 associated with the second lower surface 722 and placed in the recess 59 associated with the recess 57 for external connection, respectively; wherein due to the thickness of said first conductive layer 91 is less than 10 μm (0.01 mm) usually, then said first conductive layer 91 can be employed as a portion of said conductive element 70, in this manner, the first upper surface 711 and the second lower surface 722 of said conductive element 70 can be formed by said first conductive layers 91 as required; said bond pad 23 of chip 20 is electrically connected to said first conductive layer 91 on said first upper surface 711 of conductive element 70 through the two ends of said conductive wire 60; Accordingly, By means of being conjoined with chip 20 and conductive wire 60. it allows said substrate 55 to be used more conveniently, meanwhile, said substrate 55 can be serving as a semiconductor package as required.

As shown in FIG. 14, the substrate 55 in FIG. 14 is an alternative of the substrate 50 shown in FIG. 8; the structure of substrate 55 (shown in FIG. 14) is similar to the structure of substrate 50 (shown in FIG. 8), wherein the difference between the substrate 55 shown in FIG. 14 and the substrate 50 shown in FIG. 8 is the substrate 55 (shown in FIG. 14) further includes a glue 80, a chip 20, two first conductive layers 91, a conductive mean which is employed as a conductive wire 60, a third insulator 45, and a recess 59 formed by the first upper surface 711 and the insulator 40; both said glue 80 and said chip 20 are placed in the through hole 58 of said insulator 40 of said substrate 55, wherein both the side edge 24 of chip 20 and the second surface 22 of chip 20 are encapsulated by said glue 80, in this manner, said chip 20 is coupled with said insulator 40 by said glue 80, nevertheless, the first surface 21 of chip 20 is not encapsulated but exposed to said glue 80 for external connection, therefore, it is not necessary for the thickness of said substrate 55 to be comprised of the thickness of said chip 20, then the thickness of said substrate 55 enables to be thinner; said two first conductive layers 91 are situated on the first upper surface 711 associated with the second lower surface 722 and placed in the recess 59 associated with the recess 57 for external connection, respectively; said bond pad 23 of chip 20 is electrically connected to said first conductive layer 91 on said first upper surface 711 of conductive element 70 through the two ends of said conductive wire 60; said third insulator 45 having a first surface 46, a second surface 47, a side edge 48 and an opening 43, said second surface 47 of third insulator 45 situated on said first surface 41 of insulator 40, and said third insulator 45 seals said conductive wire 60, said chip 20, said glue 80, the first upper surface 711 of said conductive element 70 and said first conductive layer 91 situated on said conductive element 70, wherein a portion of the first upper surface 711 of conductive element 70 is not encapsulated by said third insulator 45 but exposed to said opening 43 of third insulator 45 for external connection; Accordingly, By means of being conjoined with chip 20 and conductive wire 60. it allows said substrate 55 to be used more conveniently, meanwhile, said substrate 55 can be serving as a semiconductor package as required; In addition, the second surface 22 of chip 20 enables to be not encapsulated but expose to the second surface 82 of said glue 80 as required;

As shown in FIG. 15, the structure of substrate 50 shown in FIG. 15 is substantially the same as the structure of substrate 50 shown in FIG. 11; wherein the substrate 50 shown in FIG. 15 is coupled with a carrier (such as a lead frame, a chip, a mother board or the like), in this manner, an electrical device 100 is formed, said electrical device 100 comprising: a carrier which is employed as a lead frame 30, said lead frame 30 having a plurality of through holes 39, a first surface 31 and a corresponding second surface 32; due to the structure of said substrate 50 shown in FIG. 15 is substantially the same as the structure of substrate 50 shown in FIG. 11 (refer to the detailed descriptions of FIG. 11), in this manner, said second surface 42 of insulator 40 of substrate 50 is coupled with said first surface 31 of lead frame 30; an electrical wire 60, wherein the bond pad 23 of chip 20 is electrically connected to the first conductive layer 91 on said first upper surface 711 of conductive element 70 through the two ends of said conductive wire 60; an another electrical wire 69, wherein the first conductive layer 91 on said first upper surface 711 of conductive element 70 is electrically connected to the first surface 31 of said lead frame 30 through the two ends of said conductive wire 69, accordingly, By means of both said conductive wire 60 and said another conductive wire 69, said chip 20 can be electrically connected to said lead frame 30, wherein said conductive wire 60 and said another conductive wire 69 are made of gold, copper or the like; an encapsulant 10 seals said substrate 50, said conductive wire 60, said another conductive wire 69 and said lead frame 30; consequently, By means of said substrate 50 being coupled with said carrier (30), then a semiconductor package 100 is formed, as this result, it is more convenient for said substrate 50 to be used in the electronic industries ; moreover, the substrate 55 shown in FIG. 13 (or FIG. 14) enables to be instead of said substrate 50 as required, wherein, in case that the substrate 55 shown in FIG. 13 is instead of said substrate 50, then the first conductive layer 91 on said second lower surface 722 of conductive element 70 of substrate 55 shown in FIG. 13 can be electrically connected to the first surface 31 of lead frame 30 and mounted thereon through solder balls (not shown) and/or solder paste (not shown).

In accordance with the foregoing descriptions accompanying drawings, this invention has been described in terms of several preferred embodiments, various alternations and modifications can be made to become apparent to those skilled in the art; For examples: as shown in FIG. 1A˜2B, wherein the second lower surface 722 of conductive element 70 also can be encapsulated by the insulator 40 as required; as shown in FIG. 1A˜7, wherein the substrate 50 can further include a third insulator 45 (refer to the detailed descriptions in FIG. 8, FIG. 9 or FIG. 10), a second conductive element 75 and/or a protective layer 15 (refer to the detailed descriptions in FIG. 9); the substrates (50,55) in accordance with the present invention can be further comprised of a through hole 58 (refer to FIG. 8) and be employed as either a mother board or flexible printing circuit board as required; as shown in FIG. 1A˜4, the insulator 40 can be substituted by the first insulator 4A and the second insulator 4B (shown in FIG. 5) as required; as shown in FIG. 11˜15, wherein the second surface 22 of chip 20 can be exposed to the insulator 40; the substrates 55 shown in FIG. 12 and FIG. 14, can further include a second conductive element 75 or a protective layer 15 (shown in FIG. 13); as shown in FIG. 6, wherein the substrate 50 can further include second conductive layers which are situated on the first conductive layers 91 respectively, and wherein said first, second, conductive layers can be interchangeable; and as shown in FIG. 7, wherein the substrate 50 can further include third conductive layers which are situated on the second conductive layers 92 respectively, and wherein said first, second and/or third conductive layers can be interchangeable; as shown in FIG. 13, wherein an further added insulator (not shown) can be situated on the first surface 46 of third insulator 45 as required, moreover, an another second conductive element (not shown) can situated on said further added insulator as required too; Accordingly, since many such various alterations and/or modifications can be made to the foregoing descriptions, it is to be understood that the scope of the invention is not limited to the disclosed embodiments but is defined by the appended claims;

What is claimed is:

1. A substrate for electrical device, comprising:
at least an insulator having at least a first surface, a corresponding second surface, and a side edge; and
at least a conductive element including an upper portion and a lower portion, said upper portion of conductive element having a first side edge, a first width, a first length, a first upper surface, and a corresponding first lower surface, wherein the first upper surface of said upper portion is also employed as the first upper surface of said conductive element; said lower portion of said conductive element having a second side edge, a second width, a second length, a second upper surface, and a corresponding second lower surface, wherein the second lower surface of said lower portion is also employed as the second lower surface of said conductive element, said upper portion of said conductive element is common unitary with said lower portion of said conductive element, wherein at least a portion of said first lower surface of said upper portion is coupled with at least a portion of said second upper surface of said lower portion, in this manner, both said upper portion of said conductive element and said lower portion of said conductive element are stack; said conductive element is encapsulated by said insulator and embedded therein, wherein at least a portion of said first lower surface of said upper portion of said conductive element and at least a portion of said first side edge of said upper portion of said conductive element being encapsulated by said insulator, and wherein said first upper surface of said conductive element exposed to said first surface of said insulator; said first length of said upper portion is longer than said second length of said lower portion, in this manner, said first lower surface of said upper portion of said conductive element is not coupled with said lower portion of said conductive element entirely, and therefore said upper portion of said conductive element is capable of extending on said first surface of insulator.

2. The substrate of claim 1, wherein said second upper surface of said lower portion and said second side edge of said lower portion are encapsulated by said insulator, and wherein said second lower surface of said lower portion exposed to said insulator.

3. The substrate of claim 1, wherein said second upper surface of said lower portion, said second side edge of said lower portion and said second lower surface of said lower portion are encapsulated by said insulator.

4. The substrate of claim 1, wherein said substrate further comprising at least a recess which is selectively formed by said first upper surface of upper portion of conductive element and said insulator or said first lower surface of lower portion of said conductive element and said insulator.

5. The substrate of claim 2, wherein a portion of said second side edge of said lower portion or a portion of said first side edge of said upper portion being exposed to said insulator.

6. The substrate of claim 1, wherein said upper portion of conductive element further comprising at least a third lower surface which is between said first lower surface of said upper portion and said second side edge of lower portion, and wherein both said third lower surface of said upper portion and said second side edge of lower portion are not encapsulated by said insulator but exposed to said insulator, in this manner, at least a slot formed by said second side edge of lower portion, said third lower surface of said upper portion and said insulator.

7. The substrate of claim 1, wherein said substrate further comprising at least a first conductive layer which is situated on said conductive element, and wherein at least a portion of said first conductive layer exposed to said insulator.

8. The substrate of claim 2, wherein said second width of said lower portion is wider than said first width of said upper portion, in this manner, said second upper surface of lower portion is not coupled with said first lower surface of said upper portion entirely, and therefore, at least a portion of said lower portion is capable of extending on said second surface of insulator.

9. The substrate of claim 1, wherein said substrate further comprising at least a third insulator having a side edge, a first surface, and a corresponding second surface; wherein said second surface of said third insulator is coupled with said insulator.

10. The substrate of claim 9, wherein said substrate further comprising at least a second conductive element, and said third insulator further including at least an opening, wherein, a portion of said conductive element is exposed to said opening of third insulator; said second conductive element is situated on the first surface of said third insulator and is electrically connected to said conductive element through said opening of third insulator.

11. The substrate of claim 1, wherein said substrate further comprising at least a through hole.

12. The substrate of claim 7, said substrate further comprising at least a chip having a first surface, a second surface, a side edge, and at least a bond pad; said bond pad is disposed on the first surface of said chip, wherein at least a portion of said side edge of said chip is encapsulated by said insulator, in this manner, said chip is embedded in said insulator, wherein said first surface of chip is exposed to said insulator, and said chip is adjacent to said conductive element.

13. The substrate of claim 12, said substrate further comprising at least a conductive mean, wherein said conductive mean electrically connected said chip to said conductive element, and wherein said conductive mean is selectively serving as a conductive wire or a conductive paste.

14. The substrate of claim 7, said substrate further comprising at least a through hole, a chip, and a glue; wherein said chip having a first surface, a second surface, a side edge, and at least a bond pad; said bond pad is disposed on the first surface of said chip, wherein both said glue and said chip are placed in said through hole of said substrate, and at least a portion of the side edge of said chip is encapsulated by said glue, in this manner, said chip is coupled with said insulator by said glue, and the first surface of said chip is exposed to said glue.

15. The substrate of claim 14, said substrate further comprising at least a conductive mean, wherein said conductive mean electrically connected said chip to said conductive element, and wherein said conductive mean is selectively serving as a conductive wire or a conductive paste.

16. The substrate of claim 1, wherein said insulator of said substrate is comprised of at least a first insulator and a second insulator which are stack.

17. A substrate for electrical device, comprising:
at least an insulator having at least a first surface, a corresponding second surface, and a side edge;
at least a conductive element including a first side edge, a first upper surface, and a corresponding first lower surface, wherein said first side edge of said conductive element is encapsulated by said insulator in this manner, said conductive element is embedded in said insulator, and wherein said first upper surface of said conductive element exposed to said first surface of said insulator;
at least a first conductive layer, said first conductive layer is situated on said first upper surface of said conductive element; and
at least a chip having a first surface, a second surface, a side edge, and at least a bond pad; said bond pad is disposed on the first surface of said chip, wherein at least a portion of said side edge of said chip is encapsulated by said insulator, in this manner, said chip is embedded in said insulator, and said chip is adjacent to said conductive element, wherein said first surface of said chip is exposed to said insulator.

18. The substrate of claim 17, wherein said substrate further comprising at least a conductive mean, wherein said conductive mean electrically connected said chip to said conductive element, and wherein said conductive mean is selectively serving as a conductive wire or a conductive paste.

19. The substrate of claim 18, wherein said substrate further comprising at least a third insulator having a side edge, a first surface, and a corresponding second surface; wherein said second surface of said third insulator is coupled with said insulator.

20. The substrate of claim 19, said substrate further comprising at least a second conductive element, and said third insulator further including at least an opening, wherein, a portion of said conductive element is exposed to said opening of third insulator; said second conductive element is situated on the first surface of said third insulator and is electrically connected to said conductive element through said opening of third insulator.

21. The substrate of claim 17, wherein said substrate further comprising at least a recess which is formed by said first upper surface of upper portion of conductive element and said insulator, and wherein said first conductive layer being placed in said recess of said substrate, and wherein at least a portion of the side edge of said first conductive layer being encapsulated by said insulator.

22. The substrate of claim 17, wherein said first lower surface of said conductive element being exposed to said insulator.
